(19) United States
(12) Patent Application Publication
(10) Pub. No.: US 2002/0090015 A1
(43) Pub. Date: Jul. 11, 2002

(54) Semiconductor laser module and method of making the same

(75) Inventors: Yoichi Nakajima, Tokyo (JP); Yoshiharu Taga, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD, Tokyo (JP)

(21) Appl. No.: 09/988,523

(22) Filed: Nov. 20, 2001

(30) Foreign Application Priority Data
Nov. 21, 2000 (JP) 2000-354730

(51) Int. Cl. H01L 21/00; H01S 3/04

(52) U.S. Cl. 372/36; 438/22

(57) ABSTRACT

The present invention provides a method of making a semiconductor laser module, the method having a first step of regulating the attitude of a package such that the lens fixation end face of the package will have a predetermined angle relative to a predetermined reference axis, a second step of placing a condensing lens on the lens fixation end face of the package, a third step of detecting the inclination of the laser beam passed through the condensing lens relative to the reference axis, a fourth step of fixing the condensing lens to the lens fixation end face at a position wherein the inclination of the laser beam relative to the reference axis falls within a predetermined range of angle and moving the condensing lens to the position if the inclination is out of the predetermined range of angle, thereby fixing the condensing lens to the lens fixation end face at that position, and a fifth step of aligning and fixing the optical fiber such that the desired amount of laser beam passed through the fixed condensing lens will optically be coupled with the optical fiber.

### BACKGROUND OF THE INVENTION

The present invention relates to a semiconductor laser module and a method of making the same.

FIG. 7 is a side cross-sectional view of a semiconductor laser module showing the internal structure thereof. As shown in FIG. 7, the semiconductor laser module comprises a hermetically sealed package 1, a semiconductor laser element 2 located within the package I for outputting a laser beam, an optical fiber 3 for receiving the laser beam from the semiconductor laser element 2, a photodiode 4 for receiving a monitoring laser beam from the back facet of the semiconductor laser element 2 (left side in FIG. 7), a chip carrier 5 on which the semiconductor laser element 2 is fixedly mounted, a photodiode carrier 6 on which the photodiode 4 is fixedly mounted, and a base 7 on which the chip and photodiode carriers 5, 6 are fixedly mounted.

In front of the semiconductor laser element 2 on the base 7, there is located a collimation lens 8 for collimating the laser beam from the semiconductor laser element 2. The collimation lens 8 is held by a first lens holder 9 which is formed of metal such as stainless steel and which is located on the base 7.

A flange 1a is formed on the package 1 at one side and includes a window 10 for receiving the laser beam after passed through the collimation lens 8 and a condensing lens 11 for condensing the laser beam. The condensing lens 11 is held by a second lens holder 12 which is fixedly mounted on the outer or lens fixation end face 13 of the flange 1a through YAG laser welding.

A metallic slide ring 14 is fixedly mounted on the outer end of the second lens holder 12 through YAG laser welding.

The tip end of the optical fiber 3 is held by a metallic ferrule 15 which is fixedly mounted in the slide ring 14 through YAG laser welding.

The base 7 is fixedly mounted on a cooling device 17 which is fixedly mounted on the internal bottom of the package 1. The cooling device 16 includes a Peltier device for cooling the semiconductor laser element 2. The raised temperature due to the heat from the semiconductor laser element 2 is sensed by a thermistor (not shown) on the chip carrier 5. The cooling device 16 is controlled such that the temperature sensed by the thermistor will be maintained constant. Thus, the laser output of the semiconductor laser element 2 can be stabilized.

The laser beam outputted from the front facet of the semiconductor laser element 2 is collimated by the collimation lens 8 and condensed by the condensing lens 11 through the window 10 into the optical fiber 3 which in turn delivers the condensed laser beam externally.

On the other hand, the monitoring laser beam outputted from the back facet of the semiconductor laser element 2 is received by the photodiode 4. When the current passing through the semiconductor laser element 2 is regulated so that the amount of light received by the photodiode 4 will be maintained constant, the intensity in the laser beam from the front facet of the semiconductor laser element 2 can also be regulated.

In recent years, the study and development in the field of semiconductor laser module have been made relating to how to extract the desired power from the optical fiber 3 when the laser beam from the semiconductor laser element 2 is optically coupled with the optical fiber 3.

In order to extract the desired power from the optical fiber 3, it is required that the laser beam from the condensing lens 11 enters the optical fiber 3 with the optimal incident angle. For such a purpose, the condensing lens 11 has carefully been aligned.

### SUMMARY OF THE INVENTION

The present invention provides a method of making a semiconductor laser module comprising a semiconductor laser element for outputting a laser beam, a condensing lens for condensing the laser beam from the semiconductor laser element, an optical fiber for receiving the condensed laser beam from the condensing lens and a package including a lens fixation end face for fixedly mounting said condensing lens on said package, said method comprising:

a first step of regulating the attitude of said package such that the lens fixation end face of said package in which said semiconductor laser element is mounted will have a predetermined angle relative to a predetermined reference axis;

a second step of placing said condensing lens on the lens fixation end face of said package;

a third step of detecting the inclination of the laser beam passed through said condensing lens relative to said reference axis;

a fourth step of fixing said condensing lens to said lens fixation end face at a position wherein the inclination of the laser beam relative to said reference axis falls within a predetermined range of angle and moving said condensing lens to said position if said inclination is out of the predetermined range of angle, thereby fixing said condensing lens to said lens fixation end face at that position; and

a fifth step of aligning and fixing said optical fiber such that the desired amount of laser beam passed through said fixed condensing lens will optically be coupled with said optical fiber.

The present invention also provides a semiconductor laser module comprising a semiconductor laser element for outputting a laser beam, a condensing lens for condensing the laser beam from the semiconductor laser element, an optical fiber for receiving the condensed laser beam from the condensing lens and a package including a lens fixation end face for fixedly mounting said condensing lens on said package, said package being regulated in attitude such that the lens fixation end face of said package will be perpendicular to the reference axis, said condensing lens being fixed to the lens fixation end face at a position wherein the inclination of the laser beam relative to said reference axis falls within a predetermined range of angle, and said optical fiber being aligned and fixed such that the desired amount of laser beam passed through said fixed condensing lens will optically be coupled with said optical fiber.

### BRIEF DESCRIPTION OF THE DRAWINGS

FIG. 1 is a flowchart illustrating a method of making a semiconductor laser module according to one embodiment of the present invention.

FIG. 2 is a view illustrating an aligning device usable in a step of regulating the attitude of the package such that the lens fixation end face of the flange thereof will be perpendicular to a reference axis.

FIGS. 3A and B illustrate a step of confirming whether or not the bright spot of the laser beam is within a predetermined range about the center in the lens fixation end face of the package flange.

FIGS. 4A-C illustrates a step of detecting the position of the bright spot on the first and second reference planes for the laser beam from the semiconductor laser element.

FIGS. 5A and B illustrate a step of moving the condensing lens such that the inclination of the laser beam relative to the reference axis falls within a predetermined range of angle.

FIGS. 6A and B respectively illustrate two cases, that is, a case where the first and second reference planes are located spaced equidistantly apart from the position of the laser beam focused by the condensing lens and another case where the first and second reference planes are located spaced differently apart from the position of the laser beam focused by the condensing lens.

FIG. 7 is a side cross-sectional view of a semiconductor laser module showing the internal structure thereof.

FIG. 8 illustrates a process of aligning the condensing lens according to the prior art.

### DETAILED DESCRIPTION

One embodiment of the present invention will now be described with reference to the drawings in comparison with the prior art. Throughout the drawings, similar parts are denoted by similar reference numerals. The details thereof will not repeatedly be described.

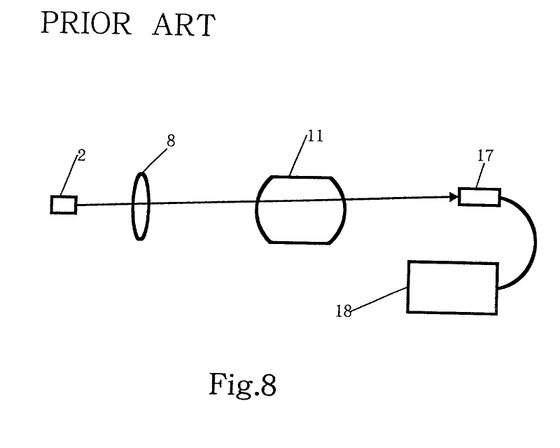

FIG. 8 illustrates a process of aligning the condensing lens according to the prior art. In FIG. 8, a laser beam outputted from a semiconductor laser element 2 passes through a collimation lens 8 and condensing lens 11 and then enters an aligning optical fiber 17. The power (brightness) of the laser beam received by the aligning optical fiber 17 is measured by a power meter 18.

By gradually changing the position of the condensing lens 11 (or the second lens holder 12), the position of the aligning optical fiber 17 is regulated such that the power optically coupled with the aligning optical fiber 17 will be maximum at the respective one of various different positions of the condensing lens 11. In such a manner, a map is prepared which represents the maximum coupling powers of the aligning optical fiber 17 at the respective positions of the condensing lens 11.

Since a point in the prepared map indicating the maximum power is the optimal position of the condensing lens 11, the second lens holder 12 holding the condensing lens 11 is fixed to the flange 1a of the package 1 at that position through YAG laser welding. Thereafter, the optical fiber 3 is again regulated in position and fixed to the ferrule at a position in which the power optically coupled with the optical fiber 3 becomes maximum.

Thus, the aligning process of the prior art relating to the condensing lens 11 required long time. As a result, time required to make the semiconductor laser module was prolonged, thereby increasing the manufacturing cost.

On the contrary, the present invention can greatly reduce time required to align the condensing lens by detecting the inclination in the laser beam relative to the reference axis after the laser beam has passed through the lens and moving the condensing lens such that the detected inclination of the laser beam is within a predetermined range of angle, in comparison with the prior art using the aligning optical fiber.

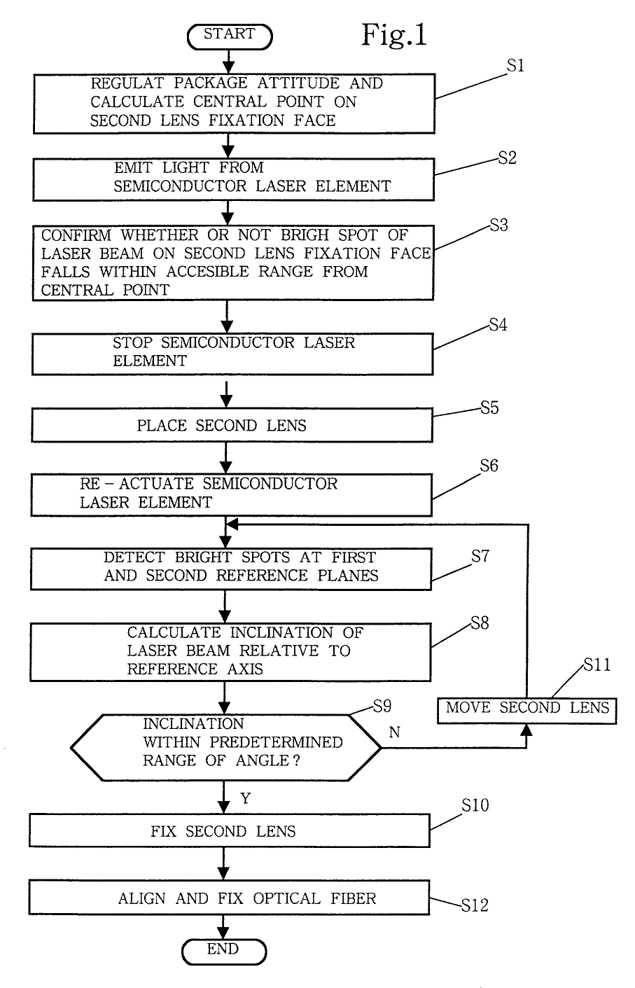

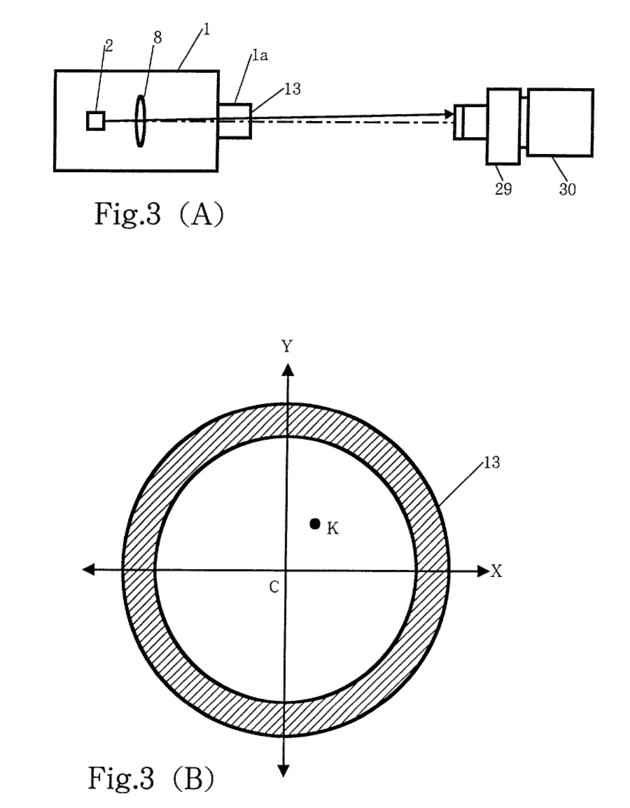

FIG. 1 is a flowchart illustrating a method of making a semiconductor laser module according to one embodiment of the present invention. First of all, the attitude of the package 1 is regulated such that the lens fixation end face 13 of the package flange 1a is perpendicular (or right angle) to the reference axis S in an optical measuring unit 21 while at the same time the central point C in the end face 13 (see FIG. 3) is calculated (step S1).

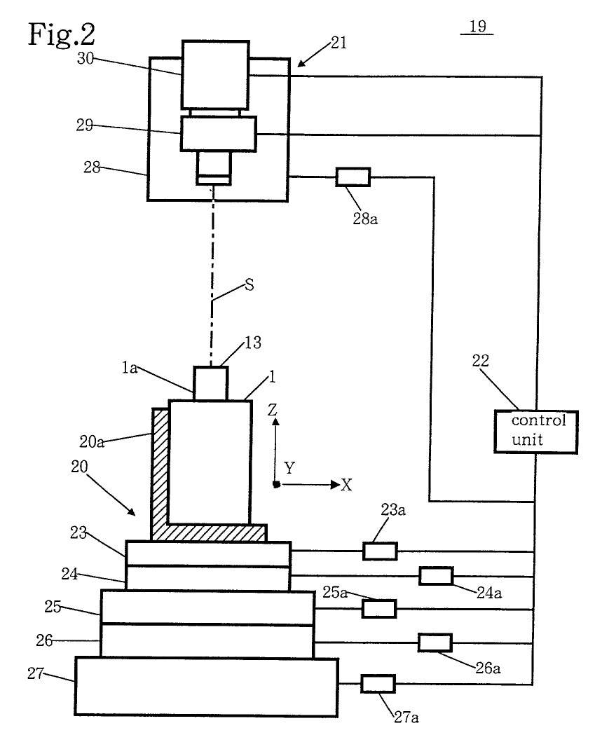

In the step S 1, such an aligning device 19 as shown in FIG. 2 may be used. The aligning device 19 comprises a regulation platform 20 and a control unit 22 in addition to the optical measuring unit 21.

The regulation platform 20 includes a Z-axis stage 27 on which X-axis angle regulating stage 23, Y-axis angle regulating stage 24, X-axis linear motion regulating stage 25 and Y-axis linear motion regulating stage 26 are placed in the order described. The top of the X-axis angle regulating stage 23 supports a fixture 20a on which the package 1 is to be detachably mounted. The X-axis angle regulating stage 23 is rotatable about X-axis through an operating shaft 23a. The Y-axis angle regulating stage 24 supports the X-axis angle regulating stage 23 and is rotatable about Y-axis perpendicular to the X-axis through an operating shaft 24a. The X-axis linear motion regulating stage 25 supports the Y-axis angle regulating stage 24 and is movable along the X-axis through an operating shaft 25a. The Y-axis linear motion regulating stage 26 supports the X-axis linear motion regulating stage 25 and is movable along the Y-axis through an operating shaft 26a. The Z-axis stage 27 supports the Y-axis linear motion regulating stage 26 and is movable up and down along the Z-axis perpendicular to both the X- and Y-axes through an operating shaft 27a. In this regard, the Z-axis is located substantially parallel to the reference axis S.

The optical measuring unit 21 is in the form of an optical measuring system having an elevator stage 28, a length measuring sensor 29 and an infrared camera 30. The elevator stage 28 supports the length measuring sensor 29 and infrared camera 30 such that they will be moved up and down in the direction of Z-axis, and is movable up and down through an operating shaft 28a. The length measuring sensor 29 is to measure the distance between the length measuring sensor 29 and the lens fixation end face 13 functioning as the reference plane in the package 1 using an auto-focusing mechanism and connected with the operating shafts 23a-28a through the control unit 22. The infrared camera 30 is to image the bright (or emission) point of the package 1 with an infrared ray, for example, having a wavelength ranging between 0.8 and 1.6μ. Image signals of the imaged point are outputted toward the control unit 22.

The control unit 22 drivingly controls the respective operating shafts 23a-28a in the automatic manner such that the lens fixation end face 13 of the package 1 will be perpendicular to the Z-axis. In addition, the control unit 22 uses the image signals from the infrared camera 30 to calculate the positions of the bright spot in the package 1 about the Z-axis and in the directions of X- and Y-axes, the shifts (or angles) of the length measuring sensor 29 and infrared camera 30 between the reference axis S and the optical axis of the package 1 and so on.

The control unit 22 drives the length measuring sensor 29 to measure the distance between the length measuring sensor 29 and the lens fixation end face 13 of the package 1 at a plurality of points (which are equal to or more than three) on the lens fixation end face 13. The resulting distance signals are outputted toward the control unit 22. The control unit 22 then uses the inputted distance signals to calculate the rotations of the X-axis angle regulating stage 23 and Y-axis angle regulating stage 24 about the X- and Y-axes which should be made to equalize the distances between the length measuring sensor 29 and the lens fixation end face 13 at the respective measuring points.

Based on the results of calculation, the control unit 22 outputs drive signals to the respective operating shafts 23a-28a to rotate the X-axis angle regulating stage 23 and Y-axis angle regulating stage 24 about the X- and Y-axes, respectively. Thus, the distances between the length measuring sensor 29 and the lens fixation end face 13 which are measured at the plural measuring points are equalized to correct the position of the package 1 such that the lens fixation end face 13 of the package 1 will be perpendicular to the reference axis S of the optical measuring unit 21.

The aligning device 19 also calculates the central point C of the lens fixation end face 13.

Next, the semiconductor laser element 2 emits the laser beam (step S2) and confirms whether or not the position of the bright spot K in the laser beam on the lens fixation end face 13 is within an acceptable range of distance from the central point C (e.g., 500 μm) (step S3).

In the step S3, the infrared camera 30 images the bright spot K of the laser beam on the lens fixation end face 13 as shown in FIG. 3A and calculates the distance between the positions of the bright spot K and central point C as shown in FIG. 3B. If that distance is within the acceptable range, the procedure proceeds to the next step. If the distance exceeds the acceptable range, it is difficult to perform the subsequent regulation of angle since the angle of inclination θ in the laser beam will not fall within a predetermined range even though the condensing lens 11 is moved at the subsequent steps S7, S8, S9 and S 11. Therefore, the procedure cannot proceed to the next step. At this time, the package 1 in question is discarded as defective.

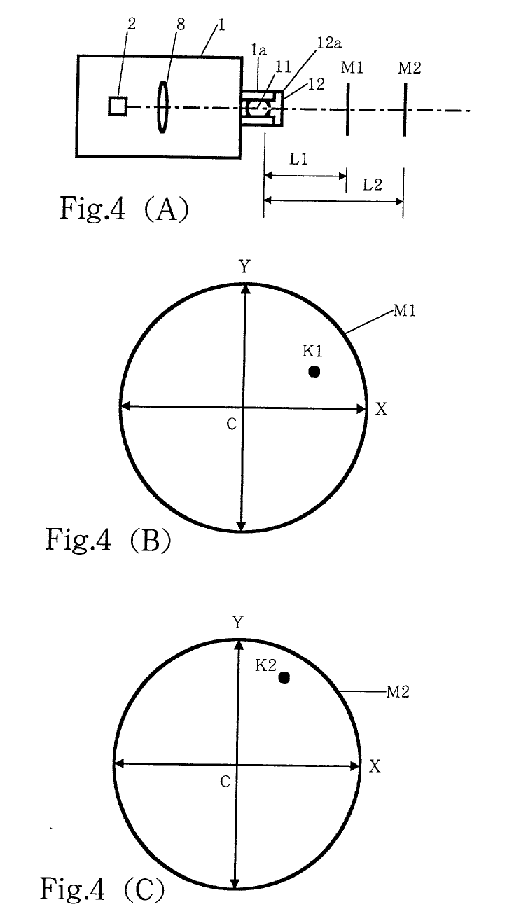

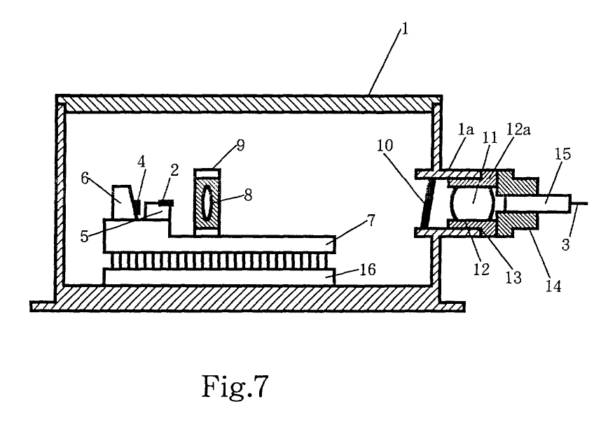

Next, the semiconductor laser element 2 is terminated (step S4) and the condensing lens 11 is placed on the lens fixation end face 13 of the package 1 (step S5). In other words, the second lens holder 12 holding the condensing lens 11 is inserted into an insert aperture in the flange 1a of the package 1 until a flange 12a in the second lens holder 12 (see FIGS. 4 and 7) is engaged by the lens fixation end face 13.

Next, the semiconductor laser element 2 is again actuated to emit the laser beam (step S6) and sets first and second reference planes M1, M2 which are respectively spaced apart from the condensing lens 11 with predetermined spacings L1 and L2 in the direction of the reference axis S and which are perpendicular to the reference axis S. The position of a bright spot K1 of the laser beam at the first reference plane M1 (see FIG. 4A) is detected while the position of a bright spot K2 of the laser beam at the second reference plane M2 (see FIG. 4C) is detected (step S7).

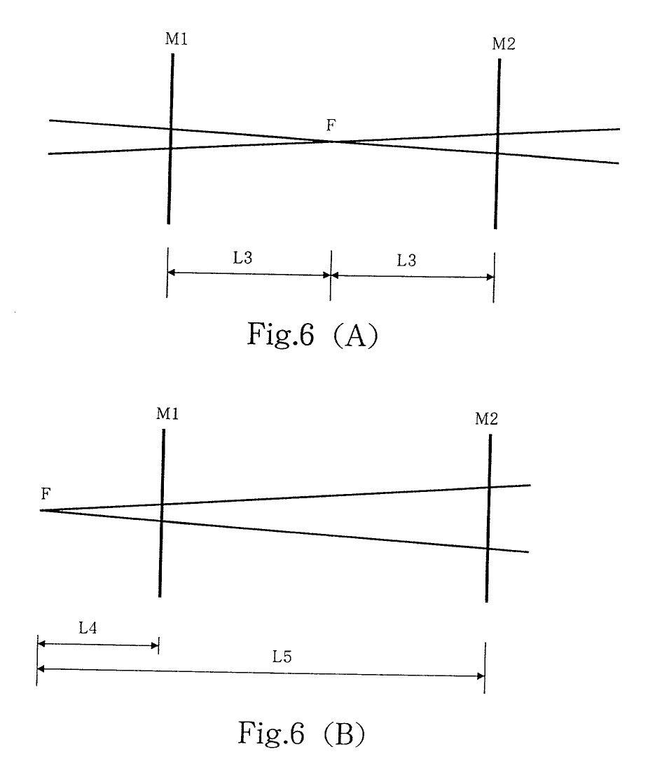

If the bright spots K1 and K2 of the laser beam at the first and second reference planes M1 and M2 are the same in magnitude and brightness, the regulation of angle can more easily be made. Thus, an arrangement wherein the first and second reference planes M1 and M2 are spaced apart from each other with an equal distance L3 about a focus point F of the laser beam through the condensing lens 11 (see FIG. 6A) is more preferable than another arrangement wherein the first and second reference planes M1 and M2 are spaced apart from each other with different distances L4 and L5 about the focus point F of the laser beam through the condensing lens 11 (see FIG. 6B). The distance L3 may be between about 1400 μm and about 1500 μm. As the distance L3 increases, the measurement accuracy increases. As the resolution in the infrared camera 30 increases, the distance L3 decreases.

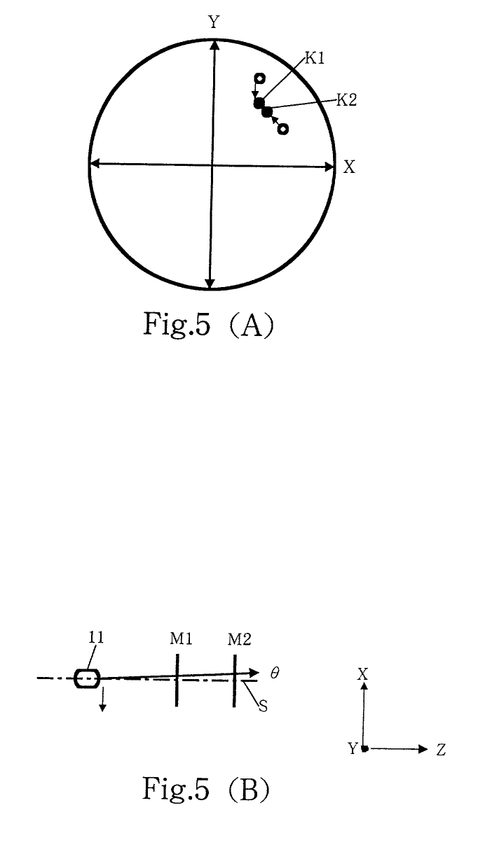

Next, the detected positions of the laser beam bright spots K at the first and second reference planes M1 and M2 as well as the spacing between the first and second reference planes M1, M2 are used to calculate the angle of inclination θ in the laser beam relative to the reference axis S as shown in FIG. 5B (step S8).

Next, it is judged whether or not the detected angle of inclination θ in the laser beam falls within a predetermined range of angle (e.g., ±0.2° or less) (step S9). If so, the condensing lens 11 is fixed to the lens fixation end face 13 using a YAG welding machine (not shown) at that point (step S10).

If the angle of inclination θ is out of the predetermined range of angle, the condensing lens 11 is moved on the X-Y plane (step S11) such that the bright spot K1 of the laser beam at the first reference plane M1 approaches to the bright spot K2 of the laser beam at the second reference plane M2 as shown in FIG. 5A. If the laser beam passing through the condensing lens 11 is in the Z-X plane and also inclines relative to the reference axis S rightward and upward (or in the direction of +X), the condensing lens 11 may be moved downward for causing the laser beam passing through the condensing lens 11 to approach the reference axis S.

As the condensing lens 11 has been moved to fall within the predetermined range of angle, the condensing lens 11 is fixed to the lens fixation end face 13 using the YAG laser welding machine (not shown) (step S10).

Finally, the optical fiber 3 is aligned and fixed through the slide ring 14 such that the desired amount of laser beam passed through the fixed condensing lens 11 will optically be coupled with the optical fiber 3 (step S12).

According to the illustrated embodiment of the present invention, the angle of inclination θ in the laser beam relative to the reference axis S is calculated by detecting and using the bright spot K in the laser beam passed through the condensing lens 11. The condensing lens 11 can be aligned by moving it such that the calculated angle of inclination θ in the laser beam will fall within the predetermined range of angle. Therefore, time required to align the condensing lens 11 can greatly be reduced in comparison with the prior art wherein the condensing lens 11 is aligned using the aligning optical fiber 17 at each time when the condensing lens 11 is moved. As a result, the semiconductor laser module can be produced for a reduced time period, thereby reducing the manufacturing cost.

Furthermore, the present invention can regulate the angle between the laser beam passed through the condensing lens 11 and the reference axis S with higher accuracy.

The present invention is not limited to the aforementioned embodiment, but may be carried out in any of various other forms without departing from the spirit and scope of the invention as defined in the appended claims.

For example, the angle between the reference axis S and the lens fixation end face 13 of the package 1 is not necessarily perpendicular to each other. This angle may suitably be changed depending on the structure of the package 1. The collimation lens 8 can be omitted and only the condensing lens 11 may be used to condense the laser beam outputted from the semiconductor laser element 2. In place of the infrared camera 30, an f-θ lens may be used to provide a single reference plane. In this case, it is preferable to use FFP observing systems which use the single reference plane to obtain the information of the laser beam relating to the angle thereof (e.g., 3267-05, 3267-06, 3267-07, 3267-11 and others manufactured by HAMAMATSU PHOTONIX Kabushiki Kaisha).

1. A method of making a semiconductor laser module comprising a semiconductor laser element for outputting a laser beam, a condensing lens for condensing the laser beam from the semiconductor laser element, an optical fiber for receiving the condensed laser beam from the condensing lens and a package including a lens fixation end face for fixedly mounting said condensing lens on said package, said method comprising:
a first step of regulating the attitude of said package such that the lens fixation end face of said package in which said semiconductor laser element is mounted will have a predetermined angle relative to a predetermined reference axis;
a second step of placing said condensing lens on the lens fixation end face of said package;
a third step of detecting the inclination of the laser beam passed through said condensing lens relative to said reference axis;
a fourth step of fixing said condensing lens to said lens fixation end face at a position wherein the inclination of the laser beam relative to said reference axis falls within a predetermined range of angle and moving said condensing lens to said position if said inclination is out of the predetermined range of angle, thereby fixing said condensing lens to said lens fixation end face at that position; and
a fifth step of aligning and fixing said optical fiber such that the desired amount of laser beam passed through said fixed condensing lens will optically be coupled with said optical fiber.

2. The method of making a semiconductor laser module as defined in claim 1, further comprising an additional step of fixing a collimation lens for collimating the laser beam from said semiconductor laser element and delivering the collimated laser beam to said condensing lens.

3. The method of making a semiconductor laser module as defined in claim 1 wherein said third step includes a step of setting first and second reference planes which are perpendicular to said reference axis at two different points spaced apart from said condensing lens with a predetermined spacing in the direction of said reference axis and a step of detecting the inclination of the laser beam passed through said condensing lens relative to said reference axis, based on the positions of bright spots in the laser beam from said semiconductor laser element on said first and second reference planes.

4. The method of making a semiconductor laser module as defined in claim 3 wherein said first and second reference planes are equidistantly set about the focus point of the laser beam formed by said condensing lens.

5. The method of making a semiconductor laser module as defined in claim 3 wherein said first and second reference planes are spaced apart from each other with an equal distance about a focus point of the laser beam.

6. A semiconductor laser module comprising a semiconductor laser element for outputting a laser beam, a condensing lens for condensing the laser beam from the semiconductor laser element, an optical fiber for receiving the condensed laser beam from the condensing lens and a package including a lens fixation end face for fixedly mounting said condensing lens on said package, said package being regulated in attitude such that the lens fixation end face of said package will be perpendicular to the reference axis, said condensing lens being fixed to the lens fixation end face at a position wherein the inclination of the laser beam relative to said reference axis falls within a predetermined range of angle, and said optical fiber being aligned and fixed such that the desired amount of laser beam passed through said fixed condensing lens will optically be coupled with said optical fiber.

7. The semiconductor laser module as defined in claim 6, further comprising a collimation lens for collimating the laser beam from said semiconductor laser element and delivering the collimated laser beam to said condensing lens.
